(19) United States
(12) Patent Application Publication
(10) Pub. No.: US 2022/0310915 A1
(43) Pub. Date: Sep. 29, 2022

(54) RESISTIVE RANDOM ACCESS MEMORY DEVICES

(71) Applicant: GLOBALFOUNDRIES Singapore Pte. Ltd., Singapore (SG)

(72) Inventors: DESMOND JIA JUN LOY, Singapore (SG); ENG HUAT TOH, Singapore (SG)

(21) Appl. No.: 17/214,901

(22) Filed: Mar. 28, 2021

(51) Int. Cl. H01L 45/00; H01L 27/24

(52) U.S. Cl. CPC H01L 45/1253; H01L 45/1233; H01L 45/146; H01L 45/1633; H01L 27/2436

(57) ABSTRACT

The present disclosure generally relates to structures, memory devices, and a method of forming the same. The structures and the memory devices may include a first electrode, a first oxygen scavenging layer disposed upon the first electrode, a resistive layer disposed upon the first oxygen scavenging layer, a second oxygen scavenging layer disposed upon the resistive layer, and a second electrode disposed upon the second oxygen scavenging layer. The structures and the memory devices may reduce the switching voltage or switching current for bidirectional switching of the resistive layer.

### FIELD OF THE INVENTION

The disclosed subject matter generally relates to structures, memory devices, and a method of forming the same. More particularly, the present disclosure relates to resistive random-access (ReRAM) memory devices.

### BACKGROUND

Semiconductor devices and integrated circuit (IC) chips have found numerous applications in the fields of physics, chemistry, biology, computing, and memory devices. An example of a memory device is a non-volatile (NV) memory device. NV memory devices are programmable and have been extensively used in electronic products due to their ability to retain data for long periods, even after the power has been turned off. Exemplary categories for NV memory may include resistive random-access memory (ReRAM), erasable programmable read-only memory (EPROM), flash memory, ferroelectric random-access memory (FeRAM), and magnetoresistive random-access memory (MRAM).

Resistive memory devices can operate by changing (or switching) between two different states: a high resistance state (HRS), which may be representative of an off or ‘0’ state; and a low resistance state (LRS), which may be representative of an on or ‘1’ state. However, these devices may require high voltage input to enable the switching of the resistance states, which increases its power consumption.

### SUMMARY

In an aspect of the present disclosure, there is provided a semiconductor structure including a first electrode, a first oxygen scavenging layer disposed upon the first electrode, a resistive layer disposed upon the first oxygen scavenging layer, a second oxygen scavenging layer disposed upon the resistive layer, and a second electrode disposed upon the second oxygen scavenging layer. The resistive layer includes a material that is different from the first and second oxygen scavenging layers, and at least one of the first and second oxygen scavenging layers includes a metal oxide.

In another aspect of the present disclosure, there is provided a memory device including a first electrode arranged above a substrate, a first oxygen scavenging layer disposed upon the first electrode, a resistive layer disposed upon the first oxygen scavenging layer, a second oxygen scavenging layer disposed upon the resistive layer, and a second electrode disposed upon the second oxygen scavenging layer. The resistive layer has a lower electron affinity than the first and second oxygen scavenging layers, and at least one of the first and second oxygen scavenging layers includes a metal oxide.

In yet another aspect of the present disclosure, there is provided a method of forming a memory device by forming a first electrode above a substrate, forming a first oxygen scavenging layer on the first electrode, forming a resistive layer on the first oxygen scavenging layer, forming a second oxygen scavenging layer on the resistive layer, in which the resistive layer includes a material having a lower electron affinity than at least one of the first and second oxygen scavenging layers, and at least one of the first and second oxygen scavenging layers includes a metal oxide, and forming a second electrode on the second oxygen scavenging layer.

### BRIEF DESCRIPTION OF THE DRAWINGS

The present disclosure may be understood by reference to the following description taken in conjunction with the accompanying drawings.

For simplicity and clarity of illustration, the drawings illustrate the general manner of construction, and certain descriptions and details of well-known features and techniques may be omitted to avoid unnecessarily obscuring the discussion of the described embodiments of the present disclosure. Additionally, elements in the drawings are not necessarily drawn to scale. For example, the dimensions of some of the elements in the drawings may be exaggerated relative to other elements to help improve understanding of embodiments of the present disclosure. The same reference numerals in different drawings denote the same elements, while similar reference numerals may, but do not necessarily, denote similar elements.

FIG. 1 is a cross sectional view of a structure in accordance with the present disclosure.

FIG. 2 is a cross sectional view of a memory device in accordance with the present disclosure.

### DETAILED DESCRIPTION

Various illustrative embodiments of the present disclosure are described below. The embodiments disclosed herein are exemplary and not intended to be exhaustive or limiting to the present disclosure.

As used herein, “deposition techniques” refer to the process of applying a material over another material (or the substrate). Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), atomic layer deposition (ALD).

Additionally, “patterning techniques” include deposition of material or photoresist, patterning, exposure, development, etching, cleaning, and/or removal of the material or photoresist as required in forming a described pattern, structure, or opening. Examples of techniques for patterning include, but not limited to, wet etch lithographic processes, dry etch lithographic processes, or direct patterning processes. Such techniques may use mask sets and mask layers.

As used herein, the terms “oxygen scavenging” or “oxygen scavenger” may refer to a composition, layer, film, or material that can consume, deplete, or react with oxygen ions from a given environment.

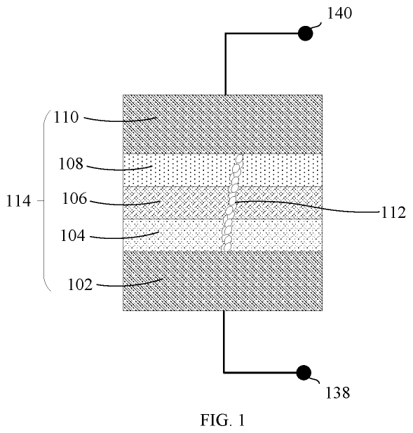

FIG. 1 illustrates a cross-sectional view of an exemplary structure 114 for use in a semiconductor device (e.g., a memory device, a logic device, an optical device, etc.). The structure 114 includes a first electrode 102, a first oxygen scavenging layer 104 disposed upon the first electrode 102, a resistive layer 106 disposed upon the first oxygen scavenging layer 104, a second oxygen scavenging layer 108 disposed upon the resistive layer 106, and a second electrode 110 disposed upon the second oxygen scavenging layer 108. The resistive layer 106 includes a material that is different from the first oxygen scavenging layer 104 and the second oxygen scavenging layer 108. In particular, the resistive layer 106 may have a lower electron affinity than the first oxygen scavenging layer 104 and the second oxygen scavenging layer 108. Preferably, the electron affinity of the oxygen scavenging layers 104, 108 may be at least two times higher than the electron affinity of the resistive layer 106. In another example, the work function values of the oxygen scavenging layers 104, 108 may be lower than the work function values of the first electrode 102 and the second electrode 110. The structure 114 may be integrated into an integrated circuit or a semiconductor device (e.g., a memory device or a logic device).

As shown, the first electrode 102, the first oxygen scavenging layer 104, the resistive layer 106, the second oxygen scavenging layer 108, and the second electrode 110 may be arranged in a vertical configuration (e.g., each structural feature can be stacked above one another).

The structure 114 may be formed by deposition of materials using the deposition techniques described herein, followed by etching of the deposited materials using the patterning techniques described herein. For example, the first electrode 102 may be deposited on a dielectric layer (not shown). The first oxygen scavenging layer 104 may be deposited on the first electrode 102. The resistive layer 106 may be deposited on the first oxygen scavenging layer 104. The second oxygen scavenging layer 108 may be deposited on the resistive layer 106. An etching step may be performed on the deposited materials to form the structure 114.

The first electrode 102 and the second electrode 110 may be structured as an inert electrode. As used herein, the term “inert electrode” may refer to a conductive material that is capable of resisting redox reactions (i.e., gain or loss of electrons). Examples of the conductive material for the first electrode 102 and the second electrode 110 may include, but not limited to, ruthenium (Ru), platinum (Pt), titanium nitride (TiN), tantalum nitride (TaN), or gold (Au). Preferably, the first electrode 102 and the second electrode 110 may have a thickness in the range of about 5 nm to about 10 nm.

The first electrode 102 and the second electrode 110 may be oppositely biased. For example, the first electrode 102 may be positively biased while the second electrode 110 may be negatively biased, or alternatively, the second electrode 110 may be positively biased while the first electrode 102 may be negatively biased. The first electrode 102 and the second electrode 110 may be connected to electrical terminals 138, 140. An electric signal may be applied to the first electrode 102 and the second electrode 110 through the respective electrical terminals 138, 140. The electric signal may be in the form of a switching voltage or a switching current, and may be programmed to alternate between a “SET” or a “RESET” signal by changing the polarity (e.g., positive or negative) of the electrical terminals 138, 140. The electrical terminals 138, 140 may have opposite polarity with respect to each other. For example, the electrical terminal 138 is positive when the electrical terminal 140 is negative, or vice versa. A bidirectional electric signal may be applied across the first electrode 102 and the second electrode 110. As used herein, the term “bidirectional” may refer to a bi-polar electric signal capable of traveling in a first direction from the first electrode 102 to the second electrode 110 and a second direction from the second electrode 110 to the first electrode 102 when polarity of the electrical terminals 138, 140 are switched.

The resistive layer 106 may be configured to have a switchable resistance in response to a change in the electric signal. In particular, a conductive path 112, such as a filament, may form in the resistive layer 106 and the oxygen scavenging layers 104, 108, and electrically link the first electrode 102 to the second electrode 110 in response to the electric signal changes. The presence of the filament may reduce the resistance of the resistive layer 106 while the absence of the filament may increase the resistance of the resistive layer 106, thereby enabling a controllable resistive nature of the resistive layer 106. The resistive layer 106 may exhibit resistive changing properties characterized by different resistance states of the material forming this layer. These resistance states (e.g., a high resistance state (HRS) or a low resistance state (LRS)) may be used to represent one or more bits of information.

The resistive layer 106 may have a thickness that is engineered such that a relatively low voltage level may be sufficient to switch the resistance states of the resistive layer 106. Preferably, the resistive layer 106 may have a thickness in the range of about 2 nm to about 10 nm. Examples of the material for the resistive layer 106 may include, but are not limited to, carbon polymers, perovskites, silicon dioxide, oxides, or nitrides. Some examples of oxides may include lanthanide oxides, oxides of tungsten, zinc oxide, nickel oxide, niobium oxide, titanium oxide, hafnium oxide, aluminum oxide, oxides of tantalum, zirconium oxide, yttrium oxide, scandium oxide, magnesium oxide, chromium oxide, and vanadium oxide. Examples of nitrides may include boron nitride, silicon nitride, or aluminum nitride. Preferably, the resistive layer 106 may include magnesium oxide (MgO), tantalum oxide (Ta₂O₅), hafnium oxide (HfO₂), titanium oxide (TiO₂), aluminum oxide (Al₂O₃), silicon dioxide (SiO₂), tungsten oxide (WO₂), or silicon nitride (Si₃N₄).

At least one of the first 104 and second 108 oxygen scavenging layers includes a metal oxide. For example, the first oxygen scavenging layer 104 may include a metal oxide while the second oxygen scavenging layer 108 may include a metal. In another example, the first oxygen scavenging layer 104 may include a metal while the second oxygen scavenging layer 108 may include a metal oxide. In yet another example, both the first 104 and second 108 oxygen scavenging layers may include a metal oxide.

Examples of the metal oxides for the oxygen scavenging layers 104, 108 may include, but not limited to, aluminum oxide (Al₂O₃), hafnium oxide (HfO₂), oxides of tungsten (WOO, oxides of titanium (TiOₓ), or oxides of tantalum (TaₙOₓ), where “x” may be an integer in the range of 2 to 5 and “n” may be 1 or 2. Examples of the metals for the oxygen scavenging layers 104, 108 may include, but not limited to, tantalum (Ta), titanium (Ti), tungsten (W), or hafnium (Hf). Preferably, the first oxygen scavenging layer 104 and the second oxygen scavenging layer 108 may have a thickness in the range of about 1 nm to about 3 nm. In some embodiments, the thicknesses of the oxygen scavenging layers 104, 108 may be smaller than the thicknesses of the electrodes 102, 110.

A minimum energy may be required for electrical charges (e.g., electrons or ions) to overcome an energy barrier at an interface between two differing materials. For example, the electrical charges may need to gain sufficient energy to overcome the conduction energy band difference between the first electrode 102 and the resistive layer 106, as well as the conduction energy band difference between the second electrode 110 and the resistive layer 106. To reduce the energy barriers, a first oxygen scavenging layer 104 may be arranged between the resistive layer 106 and the first electrode 102, and a second oxygen scavenging layer 108 may be arranged between the resistive layer 106 and the second electrode 110. As shown in FIG. 1, the first oxygen scavenging layer 104 may be in direct contact with the resistive layer 106 and the first electrode 102, while the second oxygen scavenging layer 108 may be in direct contact with the resistive layer 106 and the second electrode 110. Accordingly, the resistive layer 106 may be positioned in between the first oxygen scavenging layer 104 and the second oxygen scavenging layer 108.

The first oxygen scavenging layer 104 and the second oxygen scavenging layer 108 may be configured to induce a movement of electrical charges. The first and second oxygen scavenging layers 104, 108 may also include a material that changes its oxidation state in response to a change in the electric signal.

In an illustrative example, the first and second oxygen scavenging layers 104, 108 may be metal oxides. A “forward” switching voltage may be applied across the first electrode 102 and the second electrode 110, in which the first electrode 102 is negatively biased while the second electrode 110 is positively biased. Negatively charged oxygen ions and electrons in the first oxygen scavenging layer 104 may be induced to move away from the first electrode 102 towards the resistive layer 106. Accordingly, the “forward” switching voltage may reduce the oxidation state of the metal oxide in the first oxygen scavenging layer 104, and in some embodiments, reduce this metal oxide to a metal. In embodiments where the first oxygen scavenging layer 104 has been reduced to a metal after the application of the “forward” switching voltage, the work function value of the metal may be lower than the work function value of the first electrode 102.

Additionally, as described herein, the electron affinity of the first oxygen scavenging layer 104, in either the reduced state or non-reduced state, may be higher than the electron affinity of the resistive layer 106. The first oxygen scavenging layer 104 may provide a graduated energy path comprising relatively lower energy barrier steps for the electrical charges (e.g., negatively charged oxygen ions and electrons) to move from the first electrode 102 to the resistive layer 106 via the first oxygen scavenging layer 104, as compared to the electrical charges moving from the first electrode 102 directly to the resistive layer 106, which may have required a steep energy path comprising a relatively larger single energy barrier step. Since each energy barrier step in the graduated energy path is smaller than the single energy barrier step of the steep energy path, the inclusion of the first oxygen scavenging layer 104 may enable a lower “forward” switching voltage to be applied across the first electrode 102 and the second electrode 110.

At the same time, the second oxygen scavenging layer 108 may scavenge the oxygen ions from the resistive layer 106 to increase the concentration or density of oxygen vacancies in the resistive layer 106. The oxygen ions scavenged by the second oxygen scavenging layer 108 may be induced to move towards the second electrode 110, thereby completing a conductive path 112 between the first electrode 102 and the second electrode 110. The oxidation state of the metal oxide in the second oxygen scavenging layer 108 may be increased.

Depending on the programming of the integrated circuit, a “reverse” switching voltage may be applied across the first electrode 102 and the second electrode 110, in which the first electrode 102 is positively biased while a second electrode 110 is negatively biased. When the switching voltage is reversed, the negatively charged oxygen ions and electrons in the second oxygen scavenging layer 108 may be induced to move from the second electrode 110 towards the resistive layer 106. Accordingly, the “reverse” switching voltage may reduce the oxidation state of the metal oxide in the second oxygen scavenging layer 108, and in some embodiments, reduce this metal oxide to a metal. In embodiments wherein the second oxygen scavenging layer 108 has been reduced to a metal after the application of the “reverse” switching voltage, the work function value of the metal may be lower than the work function value of the second electrode 110.

Additionally, as described herein, the electron affinity of the second oxygen scavenging layer 108 may be higher than the electron affinity of the resistive layer 106. The second oxygen scavenging layer 108 may provide a graduated energy path comprising relatively lower energy barrier steps for the electrical charges to move from the second electrode 110 to the resistive layer 106 via the second oxygen scavenging layer 108, as compared to the electrical charges moving from the second electrode 110 directly to the resistive layer 106, which may have required a steep energy path comprising a relatively larger single energy barrier step. Since each energy barrier step in the graduated energy path is smaller than the single energy barrier step of the steep energy path, the inclusion of the second oxygen scavenging layer 108 may enable a lower “reverse” switching voltage to be applied across the first electrode 102 and the second electrode 110.

At the same time, the first oxygen scavenging layer 104 may scavenge the oxygen ions from the resistive layer 106 to increase the concentration or density of oxygen vacancies in the resistive layer 106. The oxygen ions scavenged by the first oxygen scavenging layer 104 may be induced to move towards the first electrode 102, thereby completing a conductive path 112 in a reversed direction between the first electrode 102 and the second electrode 110. The oxidation state of the metal oxide in the first oxygen scavenging layer 104 may be increased.

In embodiments where the first oxygen scavenging layer 104 or the second oxygen scavenging layer 108 includes a metal, the first oxygen scavenging layer 104 or the second oxygen scavenging layer 108 may have a higher work function energy value than the electron affinity energy value of the resistive layer 106.

As described above, the positioning of the first oxygen scavenging layer 104 between the first electrode 102 and the resistive layer 106, and the positioning of the second oxygen scavenging layer 108 between the second electrode 110 and the resistive layer 106 may provide a graduated energy path for the electrical charges to more easily overcome the energy barriers and move more easily between the respective electrodes 102, 110 and the resistive layer 106. For example, the conduction energy band difference between the first electrode 102 and the first oxygen scavenging layer 104 and the conduction energy band difference between the first oxygen scavenging layer 104 and the resistive layer 106 may each be smaller than the conduction energy band difference between the first electrode 102 and the resistive layer 106. Hence, the electrical charges moving across the first electrode 102 to the first oxygen scavenging layer 104 and across the first oxygen scavenging layer 104 to the resistive layer 106 may require smaller energy to overcome energy barriers in graduated steps at the respective interfaces as compared to the electrical charges moving from the first electrode 102 directly to the resistive layer 106 in a single energy step without an oxygen scavenging layer positioned therebetween.

Advantageously, the positioning of both oxygen scavenging layers 104, 108 in the structure 114 may reduce the switching voltages or currents for bidirectional switching of the resistive layer 106. In particular, during bidirectional switching, the current flow across the first electrode 102 and the second electrode 110 may constantly change between a forward direction and a reverse direction. With the first oxygen scavenging layer 104 arranged between the resistive layer 106 and the first electrode 102, and the second oxygen scavenging layer 108 arranged between the resistive layer 106 and the second electrode 110, the energy required for electrical charges to overcome the energy barriers in both the forward and reverse directions may be lower compared to embodiments without oxygen scavenging layers between the resistive layer and one or both electrodes, thereby also reducing the switching voltages or currents for bidirectional switching of the resistive layer 106.

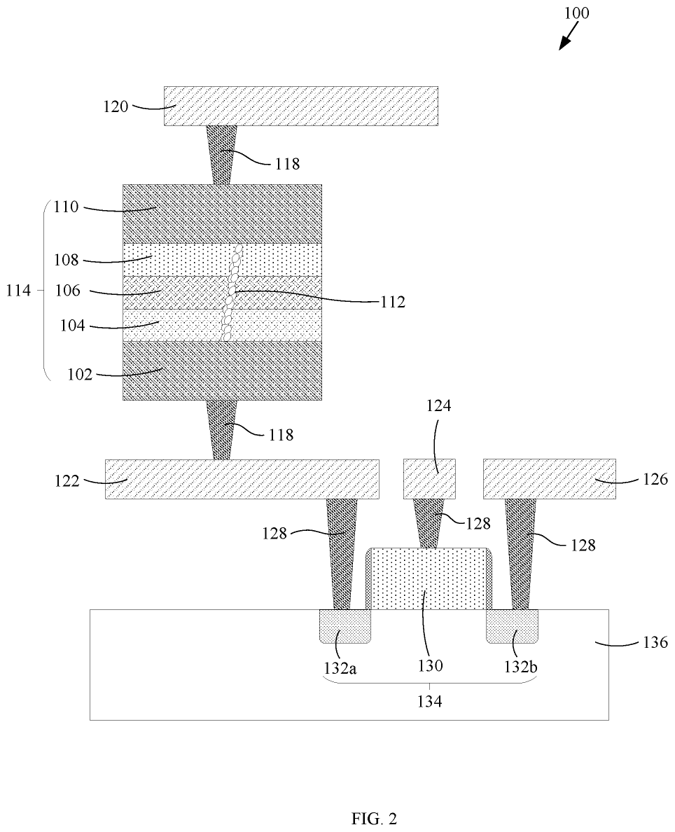

FIG. 2 illustrates a cross-sectional view of an exemplary memory device 100 integrating the exemplary structure 114 described herein. The memory device 100 described herein may be a resistive memory device. Examples of the resistive memory device may include, but are not limited to, oxide random-access memory (OxRAM). The memory device 100 may include the structure 114 being formed above a substrate 136. A transistor 134 may be formed on the substrate 136 and may include source and drain regions 132a, 132b, and a gate 130. Interconnect vias 118 contact the first electrode 102 and the second electrode 110 to electrically link the structure 114 with conductive lines 120, 122.

Interconnect vias 128 may be formed on the source and drain regions 132a, 132b, and the gate 130. The interconnect vias 128 may be electrically linked to conductive lines 122, 124, 126. The structure 114 may be electrically connected to the transistor 134. As shown in FIG. 2, the first electrode 102 may be arranged above the substrate 136. The first electrode 102 may be electrically connected to the drain region 132a of the transistor 134 through the conductive line 122. When a switching voltage is applied, the source region 132b of the transistor 134 may be connected to a ground, and the second electrode 110 may be connected to a source line, bit line, or a word line. To reverse the switching voltage, the source region 132b of the transistor 134 may be connected to a source line, bit line, or a word line, and the second electrode 110 may be connected to a ground. As used herein, the terms “source line(s)”, “word line(s)”, and “bit line(s)” may refer to electrical terminal connections.

The conductive lines 120, 122, 124, 126 may be connected to other circuitry and/or active components in the memory device. Examples of the active components (not shown) may include diodes (e.g., a bi-directional diode, a single-photon avalanche diode, etc.) or transistors such as, but not limited to, planar field-effect transistor, fin-shaped field-effect transistors (FinFETs), ferroelectric field-effect transistors (FeFETs), complementary metal-oxide semiconductor (CMOS) transistors, and bi-polar junction transistors (BJT).

Throughout this disclosure, it is to be understood that if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in an embodiment” herein do not necessarily all refer to the same embodiment.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the following detailed description.

Additionally, the various tasks and processes described herein may be incorporated into a more comprehensive procedure or process having additional functionality not described in detail herein. In particular, various processes in the manufacture of integrated circuits are well-known and so, in the interest of brevity, many processes are only mentioned briefly herein or omitted entirely without providing the well-known process details.

As will be readily apparent to those skilled in the art upon a complete reading of the present application, the disclosed semiconductor devices and methods of forming the same may be employed in manufacturing a variety of different integrated circuit products, including, but not limited to, memory cells, NV memory devices, FinFET transistor devices, CMOS devices, etc.

What is claimed is:

1. A semiconductor structure comprising:
a first electrode;
a first oxygen scavenging layer disposed upon the first electrode;
a resistive layer disposed upon the first oxygen scavenging layer;
a second oxygen scavenging layer disposed upon the resistive layer, wherein the resistive layer includes a material that is different from the first and second oxygen scavenging layers, and wherein at least one of the first and second oxygen scavenging layers includes a metal oxide; and
a second electrode disposed upon the second oxygen scavenging layer.

2. The structure of claim 1, wherein the resistive layer has a lower electron affinity than the first and second oxygen scavenging layers.

3. The structure of claim 2, wherein the first and second oxygen scavenging layers have work function values that are lower than work function values of the first and second electrodes.

4. The structure of claim 1, wherein the first and second oxygen scavenging layers include a material that changes its oxidation state in response to a change in the electric signal.

5. The structure of claim 1, wherein the first electrode, the first oxygen scavenging layer, the resistive layer, the second oxygen scavenging layer, and the second electrode are arranged in a vertical configuration.

6. The structure of claim 1, wherein the first oxygen scavenging layer includes a metal oxide and the second oxygen scavenging layer includes a metal.

7. The structure of claim 1, wherein the first oxygen scavenging layer includes a metal and the second oxygen scavenging layer includes a metal oxide.

8. The structure of claim 1, wherein the first and second oxygen scavenging layers include a metal oxide.

9. The structure of claim 1, wherein the resistive layer includes an oxide or a nitride.

10. The structure of claim 9, wherein the resistive layer includes magnesium oxide, tantalum oxide, hafnium oxide, titanium oxide, aluminum oxide, silicon dioxide, tungsten oxide, or silicon nitride.

11. The structure of claim 10, wherein the resistive layer has a thickness in the range of 2 nm to 10 nm.

12. The structure of claim 11, wherein the first oxygen scavenging layer and the second oxygen scavenging layer have a thickness in the range of 1 nm to 3 nm.

13. The structure of claim 12, wherein the first and second electrodes are structured as inert electrodes.

14. The structure of claim 13, wherein the first and second electrodes include platinum, ruthenium, gold, titanium nitride, or tantalum nitride.

15. A memory device comprising:
a first electrode arranged above a substrate;
a first oxygen scavenging layer disposed upon the first electrode;
a resistive layer disposed upon the first oxygen scavenging layer;
a second oxygen scavenging layer disposed upon the resistive layer, wherein the resistive layer has a lower electron affinity than the first and second oxygen scavenging layers, and wherein at least one of the first and second oxygen scavenging layers includes a metal oxide; and
a second electrode disposed upon the second oxygen scavenging layer.

16. The device of claim 15, further comprising a transistor formed on the substrate, wherein the first electrode is electrically connected to the transistor, and a bidirectional electric signal is applied across the first electrode and the second electrode.

17. The device of claim 16, wherein the first and second oxygen scavenging layers include a material that changes its oxidation state in response to a change in the electric signal.

18. The device of claim 17, wherein the first oxygen scavenging layer includes a metal oxide and the second oxygen scavenging layer includes a metal.

19. The device of claim 17, wherein the first oxygen scavenging layer includes a metal and the second oxygen scavenging layer includes a metal oxide.

20. A method of forming a memory device comprising:
forming a first electrode above a substrate;
forming a first oxygen scavenging layer on the first electrode;
forming a resistive layer on the first oxygen scavenging layer;
forming a second oxygen scavenging layer on the resistive layer, wherein the resistive layer includes a material having a lower electron affinity than at least one of the first and second oxygen scavenging layers, and wherein at least one of the first and second oxygen scavenging layers includes a metal oxide; and
forming a second electrode on the second oxygen scavenging layer.
